(19) United States
(12) Patent Application Publication
(10) Pub. No.: US 2025/0247650 A1
(43) Pub. Date: Jul. 31, 2025

(54) MOBILE DEVICE WITH HEADPHONE AMPLIFIER

(71) Applicant: Sennheiser electronic SE & Co. KG, Wedemark (DE)

(72) Inventors: Jan Watermann, Hannover (DE); Christian Lieber, Oberhausen (DE); Dennis Gaelings, Bocholt (DE); Julian Arnold, Kempen (DE); Simon Bongartz, Erkelenz (DE)

(73) Assignee: Sennheiser electronic SE & Co. KG, Wedemark (DE)

(21) Appl. No.: 19/041,179

(22) Filed: Jan. 30, 2025

(30) Foreign Application Priority Data
Jan. 31, 2024 (DE) 102024102776.2

(51) Int. Cl. H04R 5/04; H04R 5/033

(52) U.S. Cl. CPC H04R 5/04; H04R 5/033; H04R 2420/05; H04R 2499/11

(57) ABSTRACT

A mobile device (100) is provided with a headphone jack (102) which is suitable for connecting a headphone (200) and a headphone amplifier (101) which is configured to enable sufficient amplification for an audio signal to be reproduced. The headphone amplifier (101) comprises a level measuring unit (120) which is configured to detect a level of an incoming signal (LS, RS) to be amplified. The headphone amplifier (101) further has an impedance estimation unit (130) which is configured to detect an impedance of a connected headphone (200) on the basis of the level measurement by the level measuring unit (120) and on the basis of a current measurement at the output of a power supply unit (140). The impedance estimation unit (130) is configured to estimate an impedance of a connected headphone (200) and to initiate a change in the supply voltage if the currently applied supply voltage leads to a reduction in an efficiency of the energy supply for the headphone (200).

The present invention relates to mobile devices having a headphone amplifier.

Mobile devices such as a bodypack or a beltpack, which have a headphone amplifier to which a headphone is connected, typically have a rechargeable battery as a power supply.

In the priority application of this application, the German Patent and Trademark Office has searched the following documents: US 2017/0 180 859 A1, US 2023/0 247 362 A1 and US 2013/0 058 494 A1.

It is therefore an object of the present invention to provide a mobile device with a headphone amplifier which enables a longer battery life.

This object is achieved by a mobile device according to claim 1 and by a method for controlling a mobile device according to claim 4.

Thus, a mobile device with a headphone amplifier and a headphone jack is provided. The headphone amplifier has a level measuring unit for measuring a level of an incoming signal. The headphone amplifier further has a current measuring unit, which serves to detect a current measurement at the output of a power supply. Furthermore, the headphone amplifier has an impedance estimation unit, which carries out an impedance estimation based on the detected level and the detected current in order to obtain a suitable output voltage for the headphone. Thus, by detecting the impedance of the headphone, the power supply for the headphone can be automatically adjusted accordingly. This leads to an increased efficiency of the mobile device, since the mobile device can work with a variable output voltage for the headphone. The output voltage for the headphone can thus be adjusted to the respective impedance of the headphone.

According to one aspect of the invention, instead of one amplifier for the headphone, the headphone amplifier can be provided with two amplifiers (one amplifier for the left and one amplifier for the right).

The invention thus also relates to a mobile device with a headphone jack for connecting a headphone and a headphone amplifier that enables sufficient amplification for an audio signal to be reproduced. The headphone amplifier comprises a first amplifier for a left signal portion of the signal to be reproduced and a second amplifier for a right signal portion of the signal to be reproduced. The first and second amplifiers each have a level measuring unit that is configured to detect a level of an incoming left or right signal portion to be amplified, and an impedance estimation unit that is configured to detect an impedance of a left or right transducer of a connected headphone based on the level measurement by the level measuring unit and based on a current measurement at the output of a power supply unit.

The impedance estimation unit is configured to estimate an impedance of a left or right transducer of the connected headphone and to initiate a change in the supply voltage if the currently applied supply voltage leads to a reduction in the efficiency of the power supply for the left or right transducer of the headphone.

Further embodiments of the invention are the subject of the dependent claims.

Advantages and exemplary embodiments of the invention are explained in more detail hereinafter with reference to the drawing.

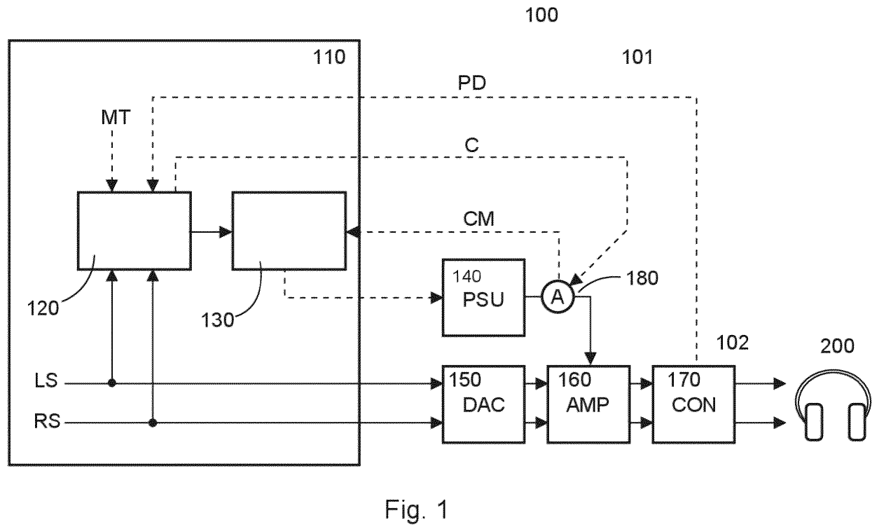

FIG. 1 shows a block diagram of a mobile device,

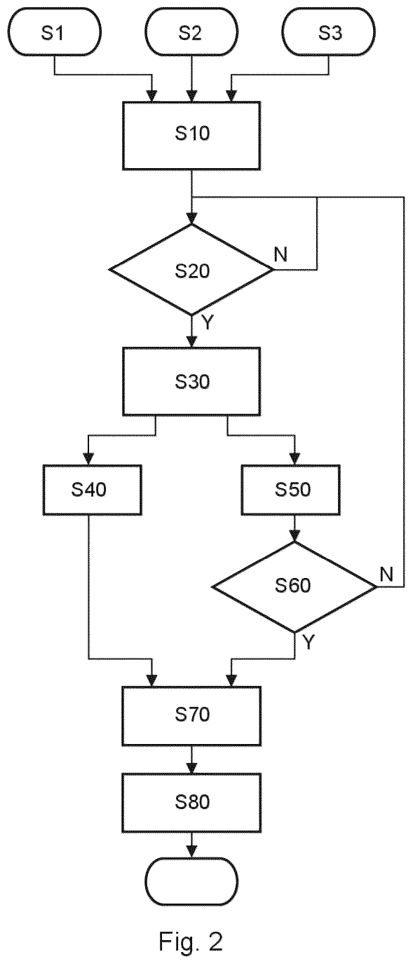

FIG. 2 shows a flow chart for controlling the mobile device,

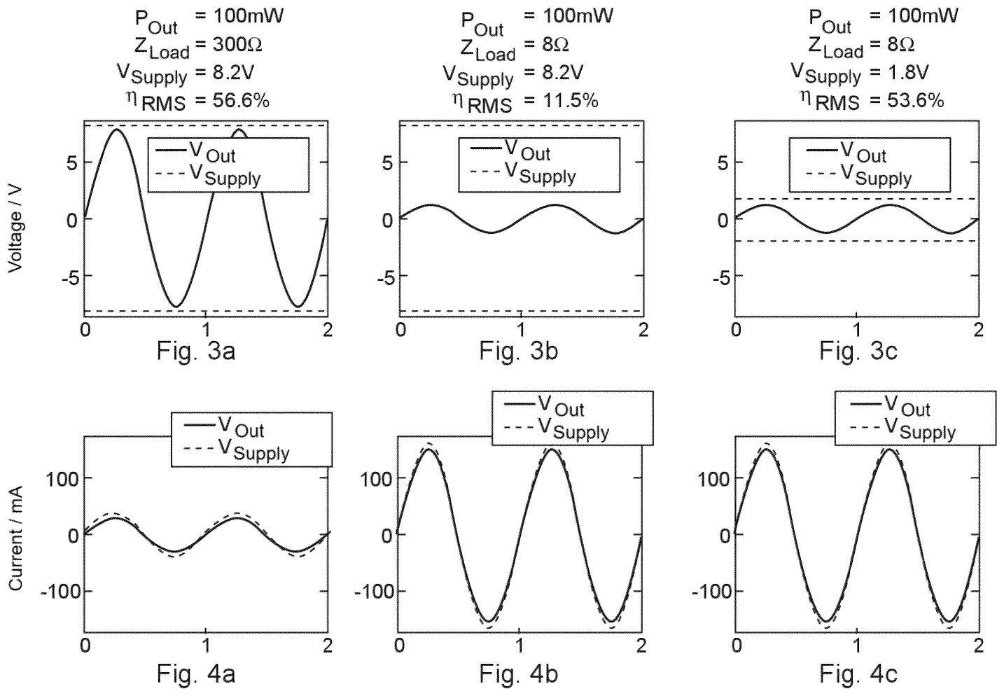

FIG. 3A shows the influence of different headphone impedances on to 3C the supply voltage for a headphone,

FIG. 4A to 4C each show a graph illustrating the influence of different headphone impedances on the current,

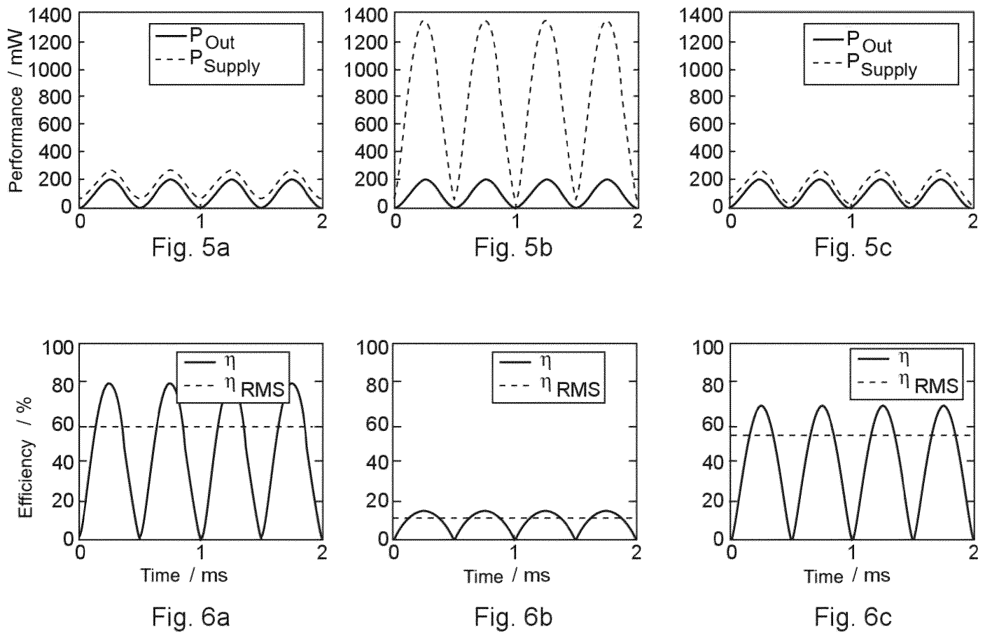

FIG. 5A to 5C each show a graph illustrating the effects of different headphone impedances on performance and

FIG. 6A to 6C each show a graph illustrating the effects of different impedances on the efficiency of the mobile device.

FIG. 1 shows a block diagram of a mobile device. The mobile device 100 comprises a headphone amplifier 101 and a headphone jack 102 to which a headphone 200 can be connected. The mobile device 100 comprises a processor 110 with a level measuring unit 120 and an impedance estimation unit 130. The level measuring unit 120 receives an audio signal (LS left, RS right). Optionally, an input for a manual trigger MF can be provided. The mobile device 100 further comprises a power supply 140, a digital/analog converter 150, an amplifier 160 and a CON unit 170. A headphone 200 can be connected to the unit 170. The unit 170 is used to detect insertion of a plug. This information from the plug detection PD is output to the level measuring unit 120. The impedance estimation unit 130 receives the detected level and a current measurement from a current measuring unit 180 and outputs a selected voltage VS to the power supply 140.

The processor 110 can receive two input signals, namely left LS and right RS, and output these signals to the digital/analog converter 150. A current measuring unit 180 is provided at the output of the power supply 140, which outputs a current measurement CM to the impedance estimation unit 130.

The level measuring unit 120 can output a control signal C for starting and stopping to the current measuring unit 180.

FIG. 2 shows a flow chart for controlling the mobile device. In step S10, the impedance measurement can be initialized. The initialization can take place when a plug was detected in step 3, when the start of an audio signal is detected in step S2, or when a device is started in step S1.

In step S20, it is checked whether the audio peak is above a threshold value. If this is not the case, then the flow leads back to the input of step S20. If the audio peak is above a threshold value, then the flow leads to step S30, where a level measurement and a current measurement are carried out. In step S40, the current measurement is carried out and the result is output to an impedance estimation unit in step S70. In step S50, a level measurement is carried out and in step S60 it is checked whether the audio level is above a threshold. If this is not the case, then the flow returns to step S20. However, if the audio level is above a threshold value, then the flow continues to step S70, where an impedance estimation is carried out. Then the flow leads to step S80, where the voltage supply is reduced to the necessary value. The method is then terminated in step S100.

An example of an impedance measurement is a measurement of the current of the positive supply voltage of the amplifier by comparing the average current consumption over a measurement period with the average value of the positive signal components in the measurement period. The measurement period can be, for example, 100 to 1000 ms.

To measure the load impedance of the headphone, a DC voltage can be applied to a series resistor and the resulting voltage at the voltage divider of the series resistor and the load are measured. With dynamic converters, this can lead to sufficiently accurate results. With other converters, however, such a measurement can lead to inaccuracies.

According to one example, other methods for measuring an impedance of the headphone may also be performed.

According to one aspect and in particular with regard to steps S20 and S60, monitoring is carried out to determine whether a sufficiently strong audio signal is present. It should be noted here that a dynamic range of the current measurement is significantly lower than the dynamic range of a real audio signal. However, in order to realize a cost-effective current measurement, the measurement result can only be evaluated when the audio signal is sufficiently strong, since the current measurement otherwise runs the risk of being drowned out by noise.

The determination of whether a sufficient SNR signal-to-noise ratio is present is based on the fact that, for example, a measurement can be started on suspicion if at least one short event above a certain threshold has been reached. It is assumed here that a sufficient average signal level is then applied over the entire measurement time. In the case of very short peaks in the audio signal without a significant average level, the average signal-to-noise ratio of the measurement would not be sufficient and could lead to a falsified measurement. For example, this result may not be known until the end of the measurement time. In such a case, the measurement must be discarded.

FIGS. 3A to 3C show the influence of different headphone impedances on the voltage.

FIGS. 4A to 4C each show a graph for illustrating the influence of different headphone impedances on the current.

FIGS. 5A to 5C each show a graph for illustrating the effects of different headphone impedances on the performance.

FIGS. 6A to 6C each show a graph for illustrating the effects of different impedances on the efficiency of the mobile device.

The graphs shown in FIGS. 3 to 6 are based on calculations using the following equations:

$$\begin{matrix}{V}_{SUPPLY , MIN} = \sqrt{2 \times {P}_{OUT , RMS} \times {R}_{LOAD}} + {V}_{HR} \\ {η}_{MAX} = \frac{{P}_{OUT , RMS}}{{V}_{SUPPLY , MIN} \times ( \sqrt{\frac{{P}_{OUT , RMS}}{{R}_{LOAD}} \times \frac{\sqrt{8}}{π} + {I}_{Q}} )} \\ η = \frac{{P}_{OUT , RMS}}{{V}_{SUPPLY , MIN} \times ( \sqrt{\frac{{P}_{OUT , RMS}}{{R}_{LOAD}} \times \frac{\sqrt{8}}{π} + {I}_{Q}} )}\end{matrix}$$

Other parameters that can have an influence here are the headroom of the amplifier between maximum output level and supply voltage (output rail-to-rail distance V_{HR} (e.g. 0.5 Volts) and the quiescent current of the amplifier I_{Q} (e.g. 5 mA). These calculations apply to sinusoidal signals.

In FIGS. 3A to 6C, a load of 300 Ohms is compared with a load of 8 Ohms at the same supply voltage. In both cases, a power of 100 mW is to be applied to the load. For the load with 300 Ohms, this results in a supply voltage of ±8.2 Volts. This leads to an efficiency of 56.6% as shown in FIG. 6A. If the supply voltage is maintained even at a low load, an efficiency of only 11.5% is achieved with a load of 8 Ohms, as shown in FIG. 6B. After a successful impedance measurement, the supply voltage can then be reduced to ±1.8 volts without any loss in audio quality (as shown in FIGS. 3C, 4C, 5C and 6C). This leads to the efficiency increasing again to 53.6% (see FIG. 6C).

According to one example, the preamplifier can detect the use of mono jack plugs (tip-sleeve TS) instead of a stereo jack plug (tip-ring-sleeve TRS). This results in the load only being applied to the left channel, whilst the right channel is short-circuited. This in turn can lead to a lower-impedance total load being detected than is actually present. In order to avoid this, the right signal can be muted in a second pass so that the impedance estimation is only performed on the left channel. The plug detection can thus be extended to include mono detection.

1. Mobile device (100), comprising
a headphone jack (102) which is suitable to connect a headphone (200), and
a headphone amplifier (101) which is configured to a enable sufficient amplification for an audio signal to be reproduced,
wherein the headphone amplifier (101)
comprises a level measuring unit (120) which is configured to detect a level of an incoming signal (LS, RS) to be amplified,
an impedance estimation unit (130) which is configured to detect an impedance of a connected headphone (200) on the basis of the level measurement by the level measuring unit (120) and on the basis of a current measurement at the output of a power supply unit (140),
wherein the impedance estimation unit (130) is configured to estimate an impedance of a connected headphone (200) and to initiate a change in the supply voltage if the currently applied supply voltage leads to a reduction in an efficiency of the power supply for the headphone (200).

2. Mobile device (100) according to claim 1, wherein
a comparison of a detected audio peak with a threshold value is performed and if the audio peak is greater than the threshold value, then the level measurement is initiated by the level measuring unit (120) and the current measurement is initiated by the current measuring unit (180).

3. Mobile device (100) according to claim 1, wherein
the level measurement is checked to determine whether it is above a threshold value, wherein if the level measurement is above a threshold value, the impedance estimation is initiated by the impedance estimation unit (130).

4. Mobile device (100), comprising
a headphone jack (102) which is suitable to connect a headphone (200), and
a headphone amplifier (101) which is configured to enable sufficient amplification for an audio signal to be reproduced,
where the headphone amplifier (101)
comprises a first amplifier for a left signal portion of the signal to be reproduced and
a second amplifier for a right signal portion of the signal to be reproduced,
wherein the first and second amplifiers each comprise
a level measuring unit (120) which is configured to detect a level of an incoming left or right signal component (LS, RS) to be amplified, and
an impedance estimation unit (130) which is configured to detect an impedance of a left or right transducer of a connected headphone (200) on the basis of the level measurement by the level measuring unit (120) and on the basis of a current measurement at the output of a power supply unit (140),
wherein the impedance estimation unit (130) is configured to estimate an impedance of a left or right transducer of the connected headphones (200) and to initiate a change in the supply voltage if the currently applied supply voltage leads to a reduction in an efficiency of the energy supply for the left or right transducer of the headphones (200).

5. A method for controlling a mobile device (100) comprising a headphone amplifier (101) and a headphone jack (102), comprising the steps:
carrying out a level measurement by a level measuring unit (120),
carrying out a current measurement by a current measuring unit (180),
performing an impedance estimation (S70) based on the level measurement and the current measurement, and
reducing or increasing the supply voltage for the headphone (200) according to the estimated impedance.
